(19) United States
(12) Patent Application Publication
(10) Pub. No.: US 2025/0157937 A1
(43) Pub. Date: May 15, 2025

(54) POWER CONVERSION DEVICE

(71) Applicant: HITACHI ASTEMO, LTD., Hitachinaka-shi, Ibaraki (JP)

(72) Inventors: Takahiro ARAKI, Tokyo (JP); Takeshi TOKUYAMA, Tokyo (JP); Shigehisa AOYAGI, Hitachinaka-shi (JP); Hideki MIYAZAKI, Hitachinaka-shi (JP)

(73) Assignee: HITACHI ASTEMO, LTD., Hitachinaka-shi, Ibaraki (JP)

(21) Appl. No.: 18/840,588

(22) PCT Filed: Mar. 16, 2023
(86) PCT No.: PCT/JP2023/010455

§ 371 Date: Aug. 22, 2024

(30) Foreign Application Priority Data
Jun. 15, 2022 (JP) 2022-096835

(51) Int. Cl. H01L 23/538; H01L 23/373; H01L 25/18; H10D 1/68; H10D 80/30

(52) U.S. Cl. CPC H01L 23/5383; H01L 23/5386; H01L 25/18; H10D 80/30; H01L 23/3736; H10D 1/68

(57) ABSTRACT

This power conversion device comprises a plurality of circuit bodies, a wiring board, and a smoothing capacitor, wherein: the wiring board has a plurality of stacked wiring parts to which the plurality of circuit bodies and the plurality of smoothing capacitors are respectively connected; and inter-phase wiring parts respectively formed between the plurality of stacked wiring parts; in the stacked wiring parts, positive electrode wires and negative electrode wires are stacked to overlap each other; in the inter-phase wiring parts, a plurality of the positive electrode wires and a plurality of the negative electrode wires are stacked to be separated from each other on a plane of the wiring board; and the inter-phase wiring parts have a via passing therethrough in the thickness direction of the wiring board.

### TECHNICAL FIELD

The present invention relates to a power conversion device.

### BACKGROUND ART

Inverters used in automobiles need to meet a demand for achieving both improvement in productivity and reduction in inductance while addressing performance of hybrid vehicles or electric vehicles by constructing main circuits using printed circuit boards for flowing energizing currents.

PTL 1 below discloses a configuration in which reduction in inductance is achieved by stacking a positive electrode wiring and a negative electrode conductor that connect each power module to corresponding one of capacitors.

### CITATION LIST

### Patent Literature

PTL 1: JP 5830480 B2

### SUMMARY OF INVENTION

### Technical Problem

Although PTL 1 discloses the configuration in which the positive electrode wiring and negative electrode wiring are stacked in all regions to cause each wiring to be provided in a mixed manner, this configuration causes a problem of increase in electric resistance because when a heat dissipating via is provided, the number of divided parts of each wiring increases to reduce a sectional area. As a result, temperature of the wiring is less likely to decrease, and thus requiring improvement in cooling performance. In view of this, an object of the present invention is to provide a power conversion device that is improved in heat dissipation while achieving both a large current and a low inductance of a board.

### Solution to Problem

A power conversion device includes: a plurality of circuit bodies each having a plurality of power semiconductor elements; a circuit board electrically connected to the circuit body and provided with a plurality of positive electrode wirings and a plurality of negative electrode wirings stacked in a thickness direction; and a plurality of smoothing capacitors provided corresponding to the plurality of circuit bodies. The circuit board includes a plurality of stacked wiring parts connected to the corresponding plurality of circuit bodies and the corresponding plurality of smoothing capacitors, and an interphase wiring part formed between the corresponding plurality of stacked wiring parts. The plurality of positive electrode wirings and the plurality of negative electrode wirings are stacked overlapping each other in the corresponding plurality of stacked wiring parts. The interphase wiring part includes the plurality of positive electrode wirings and the plurality of negative electrode wirings that are separately stacked on a plane of the circuit board, and a via passing through the circuit board in a thickness direction.

### Advantageous Effects of Invention

The present invention enables providing a power conversion device that is improved in heat dissipation while achieving both a large current and a low inductance of a board.

### BRIEF DESCRIPTION OF DRAWINGS

FIG. 1 is an electric circuit diagram illustrating a plurality of circuit bodies in a power change device.

FIG. 2 is a general view of a board of a power conversion device according to a first embodiment of the present invention.

FIG. 3 is a diagram illustrating placement regions of a stacked wiring part, an interphase wiring part, and a main circuit terminal according to the first embodiment of the present invention.

FIG. 4 is a sectional view taken along line A-A′ of FIG. 2 and illustrates a stacked wiring part.

FIG. 5 is a sectional view taken along line B-B′ of FIG. 2 and illustrates an interphase wiring part.

FIG. 6 illustrates a modification of FIG. 4 (first modification).

FIG. 7 is a sectional view of the stacked wiring part of FIG. 5 in which a cooler is disposed.

FIG. 8 is a sectional perspective view illustrating a relationship between a stacked wiring part and an interphase wiring part in a board.

FIG. 9 is a modification of FIG. 2 (second modification).

Hereinafter, embodiments of the present invention will be described with reference to the drawings. The description and drawings below are examples for describing the present invention, and are eliminated and simplified as appropriate for the sake of clarity of description. The present invention can be also implemented in various other forms. Unless otherwise specified, each component may be singular or plural.

Each drawing shows a position, a size, a shape, a range, and the like of each component that may not represent an actual position, size, shape, range, and the like to facilitate understanding of the invention. Thus, the present invention is not necessarily limited to the position, size, shape, range, and the like disclosed in each drawing.

### One Embodiment of Present Invention and General Configuration

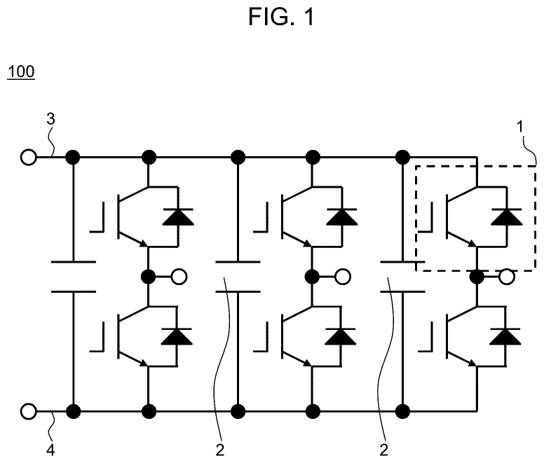

### (FIG. 1)

Each of a plurality of circuit bodies 1 constituting a power conversion circuit is composed of a semiconductor element such as an insulated gate bipolar transistor (IGBT) or a metal oxide semiconductor field effect transistor (MOSFET). Two circuit bodies 1 connected in series and one capacitor 2 are paired to form a circuit for one phase that constitutes a three-phase power conversion circuit. Each circuit is connected to a positive electrode wiring 3 and a negative electrode wiring 4.

The circuit body 1 includes three terminals of a main circuit high-voltage side terminal (collector terminal for the IGBT, drain terminal for the MOSFET), a main circuit low-voltage side terminal (emitter terminal for the IGBT, source terminal for the MOSFET), and a control terminal (gate terminal).

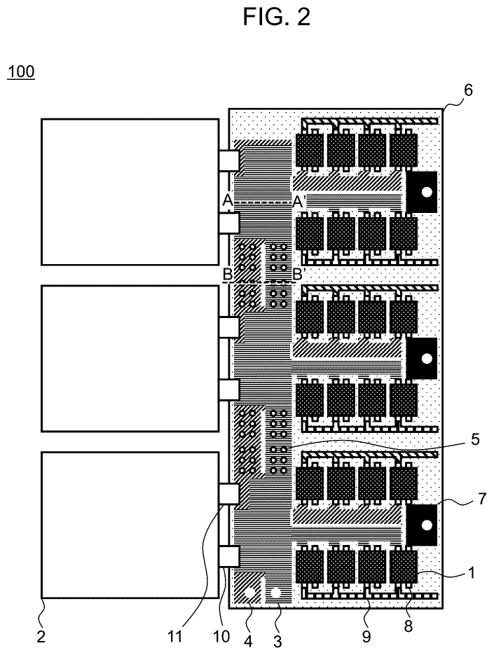

### (FIG. 2)

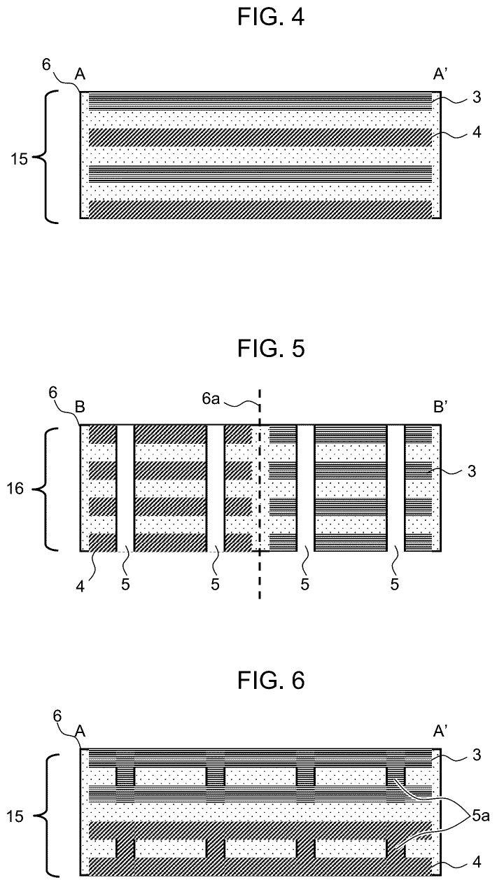

A power conversion device 100 includes a plurality of circuit bodies 1 each having a plurality of power semiconductor elements, a circuit board 6 (referred to below as a board 6) electrically connected to the circuit body 1 and provided with a plurality of positive electrode wirings 3 and a plurality of negative electrode wirings 4 stacked in a thickness direction, and a plurality of smoothing capacitors 2 provided corresponding to the plurality of circuit bodies 1. The positive electrode wiring 3 and the negative electrode wiring 4 are stacked on each other in a thickness direction of the board 6 (a forward-backward direction from the sheet of FIG. 2), and connect the capacitor 2 of each phase to the circuit body 1 (details will be described later with reference to FIGS. 4 to 8). FIG. 2 illustrates a configuration example in which four circuit bodies 1 in a row are disposed in parallel to form eight circuit bodies 1 serving as a one-phase circuit, and circuits for three phases are provided on the board 6. As described above, the circuit bodies 1 may be disposed in multiple rows in parallel to be connected to each other depending on a desired output current value.

As described above, the board 6 includes a plurality of conductor layers in the thickness direction, and each of the conductor layers is stacked with a resin layer interposed therebetween. The conductor layers of the board 6 are provided with the positive electrode wiring 3, the negative electrode wiring 4, an output wiring 7, and a signal wiring 9. The positive electrode wiring 3 and the negative electrode wiring 4 are connected to the circuit body 1 and the capacitor 2 with a bonding material such as solder. The circuit body 1 includes a signal terminal 8 for connection with the signal wiring 9. Each of the positive electrode wiring 3, the negative electrode wiring 4, and the output wiring 7 is formed thicker than the signal wiring 9 connected to the circuit body 1 to address a current to be supplied to a load of a connection destination, the current being larger than that of another wiring.

The positive electrode wiring 3 and the negative electrode wiring 4 each include a through-via 5 (referred to below as a via 5). The via 5 is provided in a region where the positive electrode wiring 3 and the negative electrode wiring 4 of each phase are not stacked on each other. Each of the plurality of positive electrode wirings 3 or the plurality of negative electrode wirings 4 passes through the board 6 in the thickness direction to form the via 5 to allow wirings equal in potential to be electrically connected to each other.

The positive electrode wiring 3 is connected to a positive electrode terminal of a DC voltage source such as a battery (not illustrated), and the negative electrode wiring 4 is connected to a negative electrode terminal of the DC voltage source such as the battery (not illustrated). As a result, a DC voltage is supplied to the circuits of the respective phases.

Capacitors 2 are connected side by side along the board 6 to satisfy a capacitor capacitance determined based on a desired variation of input voltage, and the capacitors 2 each include a positive electrode terminal 10 and a negative electrode terminal 11 as terminals to be connected to the positive electrode wiring 3 and the negative electrode wiring 4 of the board 6, respectively.

The positive electrode terminal 10 of each capacitor 2 is connected to the positive electrode wiring 3 to be electrically connected to the main circuit high-voltage side terminal of the circuit body 1 on a high side (upper arm) side. The positive electrode wiring 3 is also connected to the positive electrode terminal 10 of the capacitor 2 of another phase and the main circuit high-voltage side terminal of the circuit body 1 on the high side of the other phase. The negative electrode terminal 11 of the capacitor 2 is connected to the negative electrode wiring 4 to be connected to the main circuit low-voltage side terminal of the circuit body 1 on a low side (lower arm) side. The negative electrode wiring 4 is connected to the negative electrode terminal 11 of the capacitor 2 of the other phase and the main circuit low-voltage side terminal 12 of the circuit body 1 on the low side of the other phase. The main circuit low-voltage side terminal of the circuit body 1 on the high side is connected to the main circuit high-voltage side terminal of the circuit body 1 on the low side with the output wiring 7 of each phase. The output wiring 7 of each phase is connected to a load such as a motor (not illustrated).

The control terminal of the circuit body 1 is connected to a control circuit (not illustrated), and is turned on or off based on a signal received from a high-order control device such as a microcomputer to output an AC voltage to the load such as the motor.

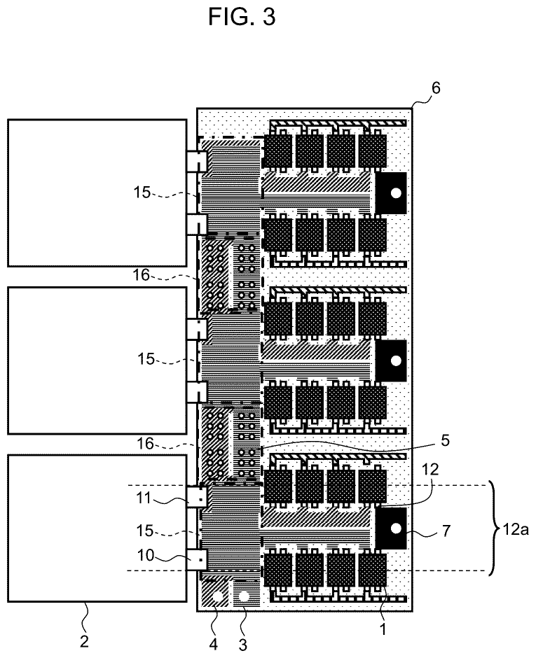

### (FIG. 3)

The board 6 includes a plurality of stacked wiring parts 15 to which the corresponding plurality of circuit bodies 1 and the corresponding plurality of smoothing capacitors 2 are connected, and an interphase wiring part 16 formed between the corresponding plurality of stacked wiring parts 15. Although the positive electrode wiring 3 and the negative electrode wiring 4 are stacked overlapping each other in the stacked wiring part 15, the plurality of positive electrode wirings 3 and the plurality of negative electrode wirings 4 are separated on the plane of the board 6, and are wired in parallel and stacked in the interphase wiring part 16. That is, the interphase wiring part 16 is a region where the positive electrode wiring 3 and the negative electrode wiring 4 are not stacked on each other in the thickness direction of the board 6.

Although the interphase wiring part 16 includes the via 5 passing through the board 6 in the thickness direction, the stacked wiring part 15 includes no via 5. The interphase wiring part 16 includes the via 5 to improve heat dissipation. In contrast, the stacked wiring part 15 includes no via 5 to form a structure in which the positive electrode wiring 3 and the negative electrode wiring 4 are not separated by the through-via 5, so that decrease in a wiring sectional area of the positive electrode wiring 3 and the negative electrode wiring 4 can be suppressed to reduce inductance.

The plurality of circuit bodies 1 includes the main circuit terminal 12 on the board 6. The main circuit terminal 12 is disposed in a region 12a perpendicular to one side defined by a distance between the positive electrode terminal 10 and the negative electrode terminal 11 of the smoothing capacitor 2. Disposing the main circuit terminal 12 in this manner enables stacked wiring connecting the capacitor 2 to the circuit body 1 to be shortened in length of wiring, so that wiring inductance of the stacked wiring part 15 is reduced to enable switching control of the circuit body 1 to be performed at a higher speed. Switching loss generated in the circuit body 1 is also reduced to enable the circuit body 1 and the whole of an inverter 100 to be downsized.

The configuration described above achieves improvement in heat dissipation while maintaining both reduction in inductance and increase in current (improvement in output) of the board 6.

### (FIGS. 4 and 5)

As illustrated in FIG. 4, the stacked wiring part 15 of the board 6 including four conductor layers, for example, includes first and third layers from an upper surface of the board 6, each of which serves as the positive electrode wiring 3, and second and fourth layers from the upper surface of the board 6, each of which serves the negative electrode wiring 4. As described above, the stacked wiring part 15 is a region where the positive electrode wiring 3 and the negative electrode wiring 4 are stacked overlapping each other. In contrast, the interphase wiring part 16 is a region provided between the stacked wiring parts 15, in which the positive electrode wiring 3 and the negative electrode wiring 4 are stacked on each other without overlapping each other as illustrated in FIG. 5. The interphase wiring part 16 electrically connects the positive electrode wiring 3 and the negative electrode wiring 4, which are equal in potential, to each other from the top to the bottom of the board 6 using the via 5 provided in the board 6 in the thickness direction.

The interphase wiring part 16 includes two or more vias 5 in each of the positive electrode wiring 3 and the negative electrode wiring 4. The vias 5 are provided in the interphase wiring part 16 and at respective positions closer to the stacked wiring part 15 adjacent to the interphase wiring part 16 than a center line 6a perpendicular to an arrangement direction of the stacked wiring part 16 and the interphase wiring part 15. As a result, when only a few vias 5 are provided, temperature of the wiring of the board 6 can be efficiently reduced. For the stacked wiring part 15 in which no via 5 is provided and wiring is less likely to be cooled, temperature of the wiring of the stacked wiring part 15 is reduced by disposing the via 5 in the interphase wiring part 16 and at a position near the stacked wiring part 15.

### (First Modification)

### (FIG. 6)

The stacked wiring part 15 allows each wiring to be stacked using a blind via 5a. That is, the positive electrode wiring 3 and the negative electrode wiring 4 can be stacked without reducing the sectional areas of the positive electrode wiring 3 and the negative electrode wiring 4 by a structure in which each of the first layer and the second layer from the upper surface of the board 6 serves as the positive electrode wiring 3, and each of the third layer and the fourth layer from the upper surface of the board 6 serves as the negative electrode wiring 4, while the wirings equal in potential are connected by the blind via 5a.

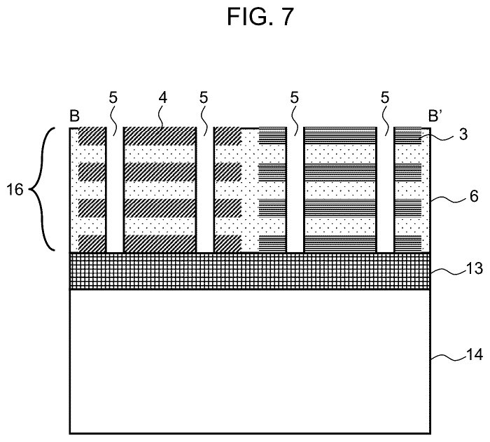

### (FIG. 7)

The board 6 is provided on one surface with a cooler 14 that cools the plurality of circuit bodies 1. Between the cooler 14 and the board 6, an insulating heat dissipation member 13 is provided. The heat dissipation member 13 improves adhesion by following a step or a warp of the board 6, and thus is made of a low-hardness resin or the like. The cooler 14 is made of a material having high thermal conductivity such as aluminum. As a result, heat generated when a current flows to the positive electrode wiring 3 and the negative electrode wiring 4 is dissipated from the board 6 through the via 5 of the interphase wiring part 16 to the cooler 14 through the heat dissipation member 13, so that temperature of the wiring of the board 6 can be reduced.

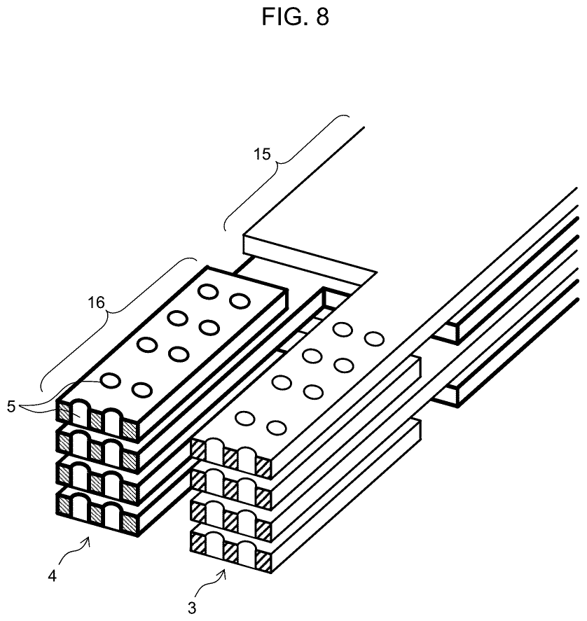

### (FIG. 8)

The stacked wiring part 15 allows the plurality of positive electrode wirings 3 and the plurality of negative electrode wirings 4 to overlap each other in the thickness direction of the board 6, thereby stacking the respective wirings. In contrast, the interphase wiring part 16 allows each of the plurality of positive electrode wirings 3 and the plurality of negative electrode wirings 4 to be individually stacked on each other without overlapping each other in the thickness direction of the board 6, so that the positive electrode wiring 3 and the negative electrode wiring 4 are disposed parallel to each other on the plane of the board 6. The interphase wiring part 16 is also provided with vias 5 for connecting wirings equal in potential to each of the positive electrode wiring 3 and the negative electrode wiring 4.

This configuration solves a conventional problem that separation of the positive electrode wiring 3 and the negative electrode wiring 4 is increased for the via 5 that is required to be provided on the board 6 in which the positive electrode wiring 3 and the negative electrode wiring 4 are mixed. When the positive electrode wiring 3 and the negative electrode wiring 4 are disposed parallel to each other in the interphase wiring part 16 as described above, a current flowing through the positive electrode wiring 3 and a current flowing through the negative electrode wiring 4 flow laterally in directions opposite to each other, and thus a magnetic field is canceled to reduce inductance. Additionally, a resonance current generated between the capacitors 2 (see FIGS. 2 and 3) disposed side by side along the board 6 is suppressed, so that loss generated in the interphase wiring part 16 is reduced as the current decreases. Furthermore, a current flowing through the interphase wiring part 16 is dispersed in all layers near the stacked wiring part 15, so that wiring heat generation can be reduced to improve heat dissipation.

### (Second Modification)

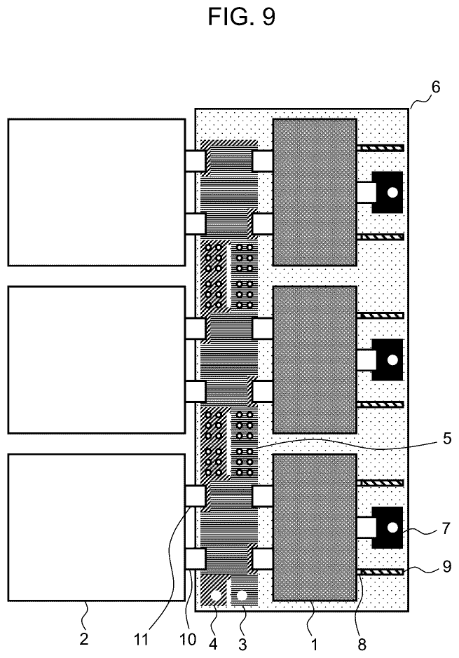

### (FIG. 9)

FIG. 9 illustrates a configuration example in which the circuit body 1 on the high side and the circuit body 1 on the low side are integrated. This configuration enables not only the circuit body 1 to be easily mounted on the board 6, but also both reduction of wiring inductance of each phase and temperature reduction of the board 6 to be achieved.

The inverter of the present invention described above with reference to FIGS. 1 to 9 may not be limited to three phases.

One embodiment of the present invention described above achieves operational effects below.

(1) The plurality of circuit bodies 1 each having a plurality of power semiconductor elements, the circuit board 6 electrically connected to the circuit body 1 and provided with the plurality of positive electrode wirings 3 and the plurality of negative electrode wirings 4 stacked in the thickness direction, and the plurality of smoothing capacitors 2 provided corresponding to the plurality of circuit bodies 1, are provided. The circuit board 6 includes the plurality of stacked wiring parts 15 to which the corresponding plurality of circuit bodies 1 and the corresponding plurality of smoothing capacitors 2 are connected, and the interphase wiring part 16 formed between the corresponding plurality of stacked wiring parts 15. The positive electrode wiring 3 and the negative electrode wiring 4 are stacked overlapping each other in the stacked wiring part 15, and the plurality of positive electrode wiring 3 and the plurality of negative electrode wiring 4 are separately stacked on the plane of the circuit board 6 in the interphase wiring part 16 that includes the via 5 passing through the circuit board 6 in the thickness direction. This configuration enables providing the power conversion device 100 that is improved in heat dissipation while achieving both a large current and a low inductance of the board.

(2) The positive electrode wiring 3 and the negative electrode wiring 4 of the interphase wiring part 16 are disposed parallel to each other on the plane of the circuit board 6. This configuration causes a current flowing through the positive electrode wiring 3 and a current flowing through the negative electrode wiring 4 to flow laterally in directions opposite to each other, and thus a magnetic field is canceled to reduce inductance.

(3) The plurality of circuit bodies 1 includes the main circuit terminal 12 on the circuit board 6, and the main circuit terminal 12 is disposed in the region 12a perpendicular to one side defined by the distance between the positive electrode terminal 10 and the negative electrode terminal 11 of the smoothing capacitor 2. This configuration enables stacked wiring connecting the capacitor 2 to the circuit body 1 to be shortened in length of wiring, so that wiring inductance of the stacked wiring part 15 is reduced to enable switching control of the circuit body 1 to be performed at a higher speed. Switching loss generated in the circuit body 1 is also reduced to enable the circuit body 1 and the whole of an inverter 100 to be downsized.

(4) The interphase wiring part 16 includes two or more vias 5 in each of the positive electrode wiring 3 and the negative electrode wiring 4. The vias 5 are provided at respective positions closer to the stacked wiring part 15 adjacent to the interphase wiring part 16 than the center line 6a of the interphase wiring part 16, the center line being perpendicular to the arrangement direction of the stacked wiring part 16 and the interphase wiring part 15. This configuration enables the stacked wiring part 15, in which wiring is less likely to be cooled, to reduce temperature of the wiring of the stacked wiring part 15 by disposing the via 5 in the interphase wiring part 16 and at a position near the stacked wiring part 15.

(5) The circuit board 6 is provided on the one surface with the cooler 14 that cools the plurality of circuit bodies 1, and the insulating heat dissipation member 13 is provided between the cooler 14 and the circuit board 6. This configuration allows heat generated when a current flows to the positive electrode wiring 3 and the negative electrode wiring 4 to be dissipated from the board 6 through the via 5 of the interphase wiring part 16 to the cooler 14 through the heat dissipation member 13, so that temperature of the wiring of the board 6 can be reduced.

The present invention is not limited to the above embodiments, and various modifications and other configurations can be combined without departing from the gist of the present invention. The present invention is also not limited to a configuration including every configuration described in each of the above embodiments, and includes a configuration in which a part of the configuration is deleted.

### REFERENCE SIGNS LIST

1 circuit body (power module)
2 capacitor
3 positive electrode wiring
4 negative electrode wiring
5 via
5a blind via
6 circuit board
6a center line
7 output wiring
8 signal terminal
9 signal wiring
10 capacitor positive electrode terminal
11 capacitor negative electrode terminal
12 circuit body main circuit terminal
12a placement region
13 heat dissipation member
14 cooler
15 stacked wiring part
16 interphase wiring part
100 power conversion device

1. A power conversion device comprising:
a plurality of circuit bodies each having a plurality of power semiconductor elements;
a circuit board electrically connected to the circuit body and provided with a plurality of positive electrode wirings and a plurality of negative electrode wirings stacked in a thickness direction; and
a plurality of smoothing capacitors provided corresponding to the plurality of circuit bodies,
wherein
the circuit board includes a plurality of stacked wiring parts connected to the corresponding plurality of circuit bodies and the corresponding plurality of smoothing capacitors, and an interphase wiring part formed between the corresponding plurality of stacked wiring parts,
the plurality of positive electrode wirings and the plurality of negative electrode wirings are stacked overlapping each other in the corresponding plurality of stacked wiring parts, and
the interphase wiring part includes the plurality of positive electrode wirings and the plurality of negative electrode wirings that are separately stacked on a plane of the circuit board, and a via passing through the circuit board in a thickness direction.

2. The power conversion device according to claim 1, wherein the positive electrode wiring and the negative electrode wiring of the interphase wiring part are disposed parallel to each other on a plane of the circuit board.

3. The power conversion device according to claim 1, wherein
the plurality of circuit bodies includes a main circuit terminal on the circuit board, and
the main circuit terminal is disposed in a region perpendicular to one side defined by a distance between a positive electrode terminal and a negative electrode terminal of the smoothing capacitor.

4. The power conversion device according to claim 1, wherein
the interphase wiring part includes two or more vias in each of the positive electrode wiring and the negative electrode wiring, and
the vias are provided at respective positions closer to the stacked wiring part adjacent to the interphase wiring part than a center line of the interphase wiring part, the center line being perpendicular to an arrangement direction of the stacked wiring part and the interphase wiring part.

5. The power conversion device according to claim 1, wherein
the circuit board is provided on one surface with a cooler that cools the plurality of circuit bodies, and
between the cooler and the circuit board, an insulating heat dissipation member is provided.
